(19) United States
(12) Patent Application Publication
(10) Pub. No.: US 2022/0384528 A1
(43) Pub. Date: Dec. 1, 2022

(54) DISPLAY SCREEN AND TERMINAL

(71) Applicant: JRD Communication (Shenzhen) LTD., Shenzhen (CN)

(72) Inventors: Guangyue LUO, Shenzhen (CN); Jie LUO, Shenzhen (CN)

(73) Assignee: JRD Communication (Shenzhen) LTD., Shenzhen (CN)

(21) Appl. No.: 17/619,590

(22) PCT Filed: Dec. 19, 2019
(86) PCT No.: PCT/CN2019/126604

§ 371 Date: Dec. 16, 2021

(30) Foreign Application Priority Data
Dec. 12, 2019 (CN) 201911271159.6

(51) Int. Cl. H01L 27/32; H01L 51/52

(52) U.S. Cl. CPC H01L 27/322; H01L 51/5268; H01L 51/5284

(57) ABSTRACT

A display screen and a terminal are provided. The display screen includes a substrate, a light-emitting layer, and a filter layer disposed in sequence. The filter layer includes a plurality of color filters with diffusion function. The display screen is provided with the color filters, so that light emitted by the light-emitting layer is diffused at various angles through diffusion particles in the color filters, thereby effectively increasing viewing angles of the display screen of the terminal.

### CROSS REFERENCE TO RELATED APPLICATIONS

The present application claims priority to Chinese Patent Application No. 201911271159.6, titled “DISPLAY SCREEN AND TERMINAL”, filed on Dec. 12, 2019 with the China National Intellectual Property Administration, which is incorporated by reference in the present application in its entirety.

### FIELD OF INVENTION

The present disclosure relates to the application field of mobile terminals, and particularly to a display screen and a terminal.

### BACKGROUND

With the evolution of technology, foldable mobile phones have been produced. Current foldable screens are similar to conventional flexible screens in stacking design, so they have obvious viewing angle characteristics. As viewing angles increase, problems of color cast and darker brightness will occur.

In the related art, a conventional organic light-emitting diode (OLED) is provided with a polarizer on a surface of a display area to reduce an influence of external light on light emitted by a screen. However, such current technical solution only solves parts of brightness problems of the display screen.

### SUMMARY OF DISCLOSURE

The present disclosure provides a display screen and a terminal, which can effectively increase viewing angles of the display screen of the terminal.

In a first aspect, the present disclosure provides a display screen comprising a substrate, a light-emitting layer, and a filter layer disposed in sequence. The filter layer comprises a plurality of color filters with diffusion function.

In a second aspect, the present disclosure provides a terminal comprising a housing, a circuit board, and a display screen. The display screen is electrically connected to the circuit board. The display screen is disposed in the housing and forms a closed space with the housing. The circuit board is disposed in the housing. The light-emitting layer and the circuit board are disposed on opposite sides of the substrate.

In the display screen provided by the present disclosure, light emitted by the light-emitting layer is diffused at various angles through diffusion particles in the color filters, thereby effectively increasing viewing angles of the display screen of the terminal.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

In order to have a more complete understanding of the present disclosure and its beneficial effects, the following description will be made with reference to the accompanying drawings, in which same reference numerals represent same components.

FIG. 1 is a perspective view of a terminal according to an embodiment of the present disclosure.

FIG. 2 is an exploded schematic diagram of the terminal according to the embodiment of the present disclosure.

FIG. 3 is a front view of the terminal according to the embodiment of the present disclosure.

FIG. 4 is a schematic structural diagram of a display screen according to an embodiment of the present disclosure.

FIG. 5 is an exploded schematic diagram of the display screen according to the embodiment of the present disclosure.

FIG. 6 is a schematic structural diagram of a filter layer of the display screen according to an embodiment of the present disclosure.

FIG. 7 is a schematic structural diagram of an arrangement of filters of the filter layer of the display screen according to an embodiment of the present disclosure.

FIG. 8 is a schematic structural diagram of a light-emitting layer of the display screen according to an embodiment of the present disclosure.

FIG. 9 is a schematic diagram of a correspondence between the filter layer and the light-emitting layer of the display screen according to an embodiment of the present disclosure.

### DETAILED DESCRIPTION

Before undertaking the detailed description below, it is advantageous to set forth definitions of certain words and phrases used throughout the present disclosure. A term “comprise” and derivatives thereof mean inclusion without limitation. A term “or” is inclusive and means “and/or”. Phrases “associated with”, “associated therewith”, and derivatives thereof may mean “comprise”, “be comprised within”, “interconnect with”, “contain”, “be contained within”, “connect to or with”, “couple to or with”, “be communicable with”, “cooperate with”, “interleave”, “juxtapose”, “be proximate to”, “be bound to or with”, “have”, “have a property of”, or the like. A term “controller” means any device, system, or part thereof that controls at least one operation. Such device may be implemented in hardware, firmware, or software, or some combination of at least two of the same. It should be noted that functionality associated with any particular controller may be centralized or distributed, whether locally or remotely. Definitions for certain words and phrases are provided throughout the present disclosure, those skilled in the art should understand that in many instances, if not most instances, such definitions apply to prior and future uses of such defined words and phrases.

Technical solutions in embodiments of the present disclosure will be clearly and completely described below in conjunction with accompanying drawings in the embodiments of the present disclosure. It is apparent that the described embodiments are merely a part of the embodiments of the present disclosure and not all embodiments. All other embodiments obtained by those skilled in the art based on the embodiments of the present disclosure without creative labor are within the claimed scope of the present disclosure.

Terms “first”, “second”, “third”, and the like (if present) in the specification, the claims, and the accompanying drawings of the present application are used to distinguish similar objects, rather than used to indicate a particular order or sequence. It should be understood that the objects so described are interchangeable under appropriate circumstances. Furthermore, terms “comprise”, “have”, and any other variation thereof are intended to cover a non-exclusive inclusion.

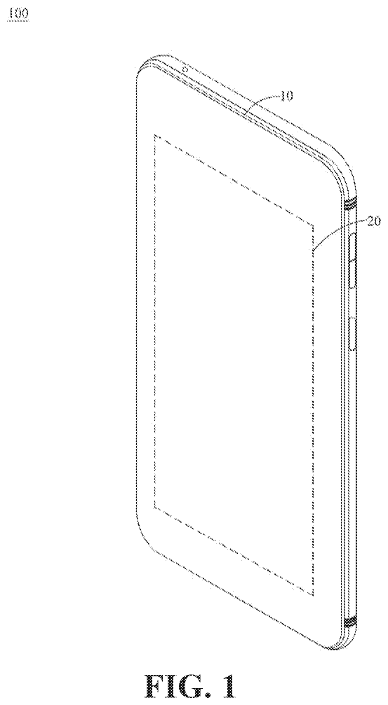

In the present disclosure, FIG. 1 to FIG. 9 discussed hereinafter and the various embodiments used to describe principles of the present disclosure are merely for illustration and should not be construed as limiting the claimed scope of the present application. Those skilled in the art will understand that the principles of the present disclosure may be implemented in any suitably arranged system. Exemplary embodiments will be described in detail, and examples of the embodiments are shown in the accompanying drawings. In addition, a terminal according to the exemplary embodiments will be described in detail with reference to the accompanying drawings in which same reference numerals represent same components.

While terms such as “first” and “second” may be used to describe various components, such components are not limited to the above terms. The above terms are used only to distinguish different components. For example, a first element could be termed a second element, and, similarly, a second element could be termed a first element, without departing from the scope of exemplary embodiments. A term “and/or” used herein comprises any and all combinations of one or more of the associated listed items.

The terms used herein are only used to describe specific embodiments and are not intended to limit concepts of the present application. Singular form is intended to comprise plural form as well unless the context clearly indicates otherwise. It should be understood that terms “comprises”, “have”, and “comprising” used herein are intended to indicate presences of features, numbers, steps, operations, components, parts, or a combination thereof disclosed in the present disclosure, but are not intended to exclude possibility that one or more other features, numbers, steps, operations, components, parts, or a combination thereof may be present or may be added. Same reference numerals in the accompanying drawings refer to same components.

According to the above problems, the present disclosure provides a display screen and a terminal, which can effectively increase viewing angles of the display screen of the terminal. Detailed descriptions are given below. It should be noted that a described order of the following embodiments is not intended to limit a preferred order of the embodiments.

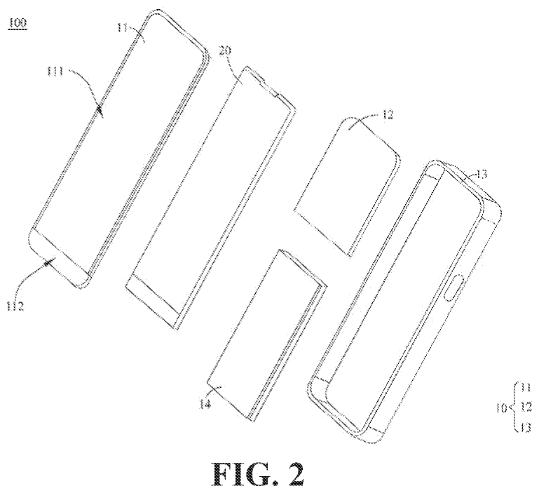

FIG. 1 is a perspective view of a terminal according to an embodiment of the present disclosure. FIG. 2 is an exploded schematic diagram of the terminal 100 according to the embodiment of the present disclosure. FIG. 1 and FIG. 2 show a smart phone as an embodiment of the terminal 100, but a terminal comprising a display screen such as a tablet personal computer (PC), a notebook PC, or a personal digital assistant (PDA) may also be used as an embodiment.

Please refer to FIG. 1 and FIG. 2, the terminal 100 according to the exemplary embodiment may comprise a terminal body 10 and a display screen 20. In this embodiment, the display screen 20 is disposed in the terminal body 10.

Please refer to FIG. 2, the terminal body 10 may comprise a cover plate 11, a printed circuit board 12, and a housing 13. Furthermore, the terminal 100 may further comprise a power source 14. The printed circuit board 12 is disposed in the housing 13. The display screen 20 may be specifically disposed in the housing 14 and may be electrically connected to the printed circuit board 12. A substrate of the display screen 20 is closest to the printed circuit board 12.

In addition, the terminal body 10 may further comprise functional components such as sensors and fingerprint modules. Those skilled in the art can understand that a structure of the terminal body 10 shown in FIG. 2 does not constitute a limitation on the terminal body of the present disclosure, and the terminal body 10 may comprise more or fewer components, or combinations thereof, or different arrangements thereof.

In some implementations, the cover plate 11 may be disposed on a front of the display screen 20. In this embodiment, “front” refers to a direction in which a surface of the display screen 20 displaying information faces, while “back” refers to a direction opposite to “front”.

The cover plate 11 may have an exposing area 111 that exposes information displayed by the display screen 20, and a non-exposing area 112 that prevents external visibility. The non-exposing area 112 may comprise a light-shielding layer, e.g., a black shielding layer, such that an inside of the terminal 100 is invisible. In some implementations, the light-shielding layer is an ink layer.

The display screen 20 is configured to display electronic files. The display screen 20 may display information such as images, videos, or texts. The display screen 20 may comprise a front surface displaying the information and a back surface located opposite to the front surface.

In some implementations, the display screen 20 may comprise a display area configured to display the information and a non-display area where no information is displayed. The display area may serve as a main display area of the display screen 20 and is configured to display most of the information. The non-display area may be disposed on a periphery of the display area. The non-display may be configured to dispose an integrated circuit (IC). The IC is configured to control display of the information on the display screen 20. The non-exposing area 112 of the cover plate 11 may be disposed on a front of the non-display area of the display screen 20 and prevent the non-display area of the display screen 20 from being seen from outside.

The housing 14 may be composed of a single component or a plurality of combinable components. As shown in FIG., the housing 14 may comprise a sidewall surface 141 and a back surface 142 connected to the sidewall surface 141. The housing 14 is made of one or more of plastic material, ceramic material, and metal material. In some implementations, the display screen 20 may be disposed in the housing 14, is connected to the sidewall surface 141 of the housing 14, and is disposed opposite the back surface 142 of the housing 14, so as to form an enclosed space.

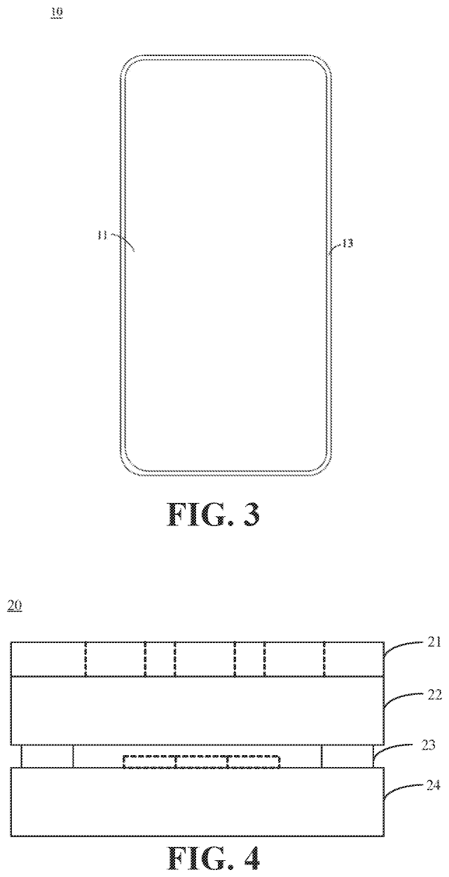

In some embodiments, please refer to FIG. 3, the terminal body 10 comprises a front surface and a sidewall surface connected to the front surface. In practical applications, the cover plate 11 may be the front surface 11 of the terminal body 10, and the sidewall surface 141 of the housing 14 is the sidewall surface 141 of the terminal body 10.

Please refer to FIG. 4, which is a schematic structural diagram of the display screen 20 according to an embodiment of the present disclosure. In some embodiments, the display screen 20 comprises a filter layer 21, a glass layer 22, a light-emitting layer 23, and a substrate 24. The filter layer 21 is disposed on a side of the glass layer 22. The light-emitting layer 23 is disposed on another side of the glass layer 22. The light-emitting layer 23 is disposed between the glass layer 22 and the substrate 24.

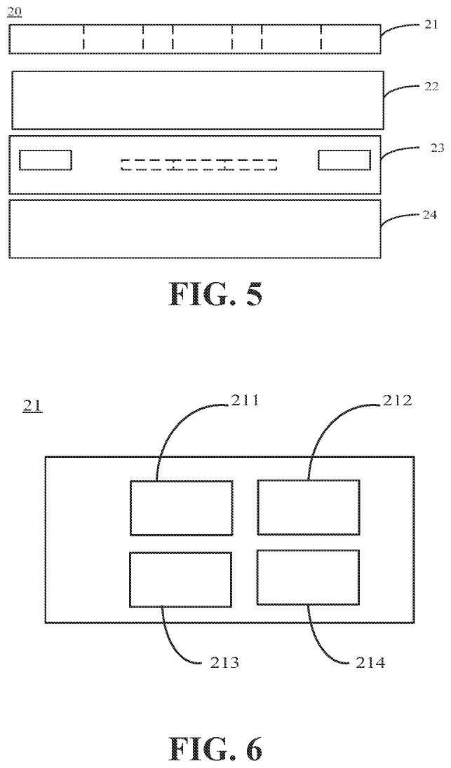

Please refer to FIG. 5, which is an exploded schematic diagram of the display screen according to the embodiment of the present disclosure. In some embodiments, the filter layer 21 may be composed of a plurality of color filters and a black matrix. The color filters may comprise red filters, green filters, and blue filters arranged at intervals. The filter layer 21 may further comprise the black matrix. The black matrix is disposed at the intervals between the red filters, the green filters, and the blue filters. Please refer to FIG. 6, the color filters may be a red filter 211, a green filter 212, and blue filters 213.

Specifically, the filter layer 21 comprises the red filter 211, the green filter 212, the blue filter 213, and a black matrix 214. The red filter 211, the green filter 212, and the blue filter 213 may comprise diffusion particles and may be filters with diffusion function. When light emitted by the light-emitting layer 23 passes through the filter layer 21, the light may be diffused out of the display screen 20 at various angles by the diffusion particles. The black matrix 214 may be configured to divide adjacent color resists, block gaps between the color resists, and prevent light leakage or color mixing.

In some embodiments, the color filters may be shaped as polygons, and the black matrix 214 may also be shaped as a polygon. For example, the color filters may be shaped as rectangles, and the black matrix 214 may also be shaped as a rectangle. The color filters may comprise a plurality of red filters, green filters, and blue filters. The black matrix may comprise a plurality of sub-black matrices. The red filters, the green filters, the blue filters, and the sub-black matrices are alternately arranged over the entire filter layer.

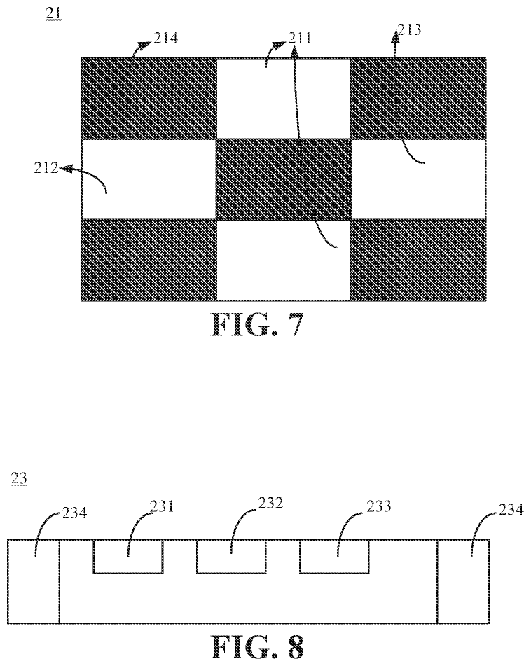

For example, please refer to FIG. 7, which is a schematic structural diagram of an arrangement of the filters of the filter layer of the display screen according to an embodiment of the present disclosure. FIG. 7 shows the arrangement of the color filters and the black matrix 214 in the filter layer 21. The red filters 211, the green filters 212, the blue filters 213, and the black matrix 214 may be shaped as rectangles and are alternately arranged on the filter layer 21. The red filters 211, the green filters 212, the blue filters 213, and the black matrix 214 may be made on the glass layer 22 by printing.

In some embodiments, the glass layer 22 is disposed between the filter layer 21 and the light-emitting layer 23. The glass layer 22 may comprise one or more pieces of glass. The glass may be encap glass. Shock resistance of the encap glass can prevent damage to the display screen 20 when the terminal is dropped, and can protect the display screen 20. In addition, the encap glass may be transparent and act as a good medium in transmission of the light emitted by the light-emitting layer 23.

In some embodiments, the light-emitting layer 23 may comprise sub-pixels and a boundary structure. Each pixel of a conventional liquid crystal panel is composed of three primary colors of red, blue, and green (RGB). Each of the colors of each pixel is called a “sub-pixel”. The light-emitting layer 23 may comprise a plurality of sub-pixels. The sub-pixels may be red sub-pixels, green sub-pixels, and blue sub-pixels. The light-emitting layer 23 can emit red light, green light, and blue light through the red sub-pixels, the green sub-pixels, and the blue sub-pixels in the energized state, respectively.

Please refer to FIG. 8, which is a schematic structural diagram of the light-emitting layer of the display screen according to an embodiment of the present disclosure. In FIG. 8, the light-emitting layer 23 may comprise red sub-pixels 231, green sub-pixels 232, blue sub-pixels 233, and a boundary structure 234. The red sub-pixels 231 can emit red light. The green sub-pixels 232 can emit green light. The blue sub-pixels 233 may emit blue light. The boundary structure 234 may be configured to prevent light leakage.

In some embodiments, the color filters of the filter layer 21 and the sub-pixels of the light-emitting layer 23 may be disposed corresponding to each other according to same color. The red filters 211, the green filters 212, and the blue filters 213 may be disposed corresponding to the red sub-pixels 231, the green sub-pixels 232, and the blue sub-pixels 233 according to same color.

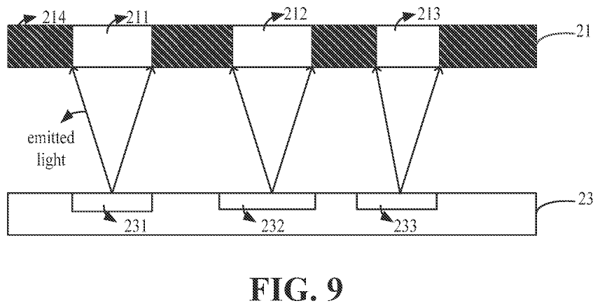

Specifically, please refer to FIG. 9, which is a schematic diagram of a correspondence between the filter layer and the light-emitting layer of the display screen according to an embodiment of the present disclosure. FIG. 9 shows the correspondence between the light emitted by the light-emitting layer 23 and the light received by the filter layer 21. For example, the red sub-pixels 231 of the light-emitting layer 23 may be disposed corresponding to the red filters 211 of the filter layer. The red light emitted by the red sub-pixels 231 may be diffused by the red filters 211. The green sub-pixels 232 may be disposed corresponding to the green filters 212 of the filter layer. The green light emitted by the green sub-pixels 232 may be diffused by the red filters 212. The blue sub-pixels 233 may be disposed corresponding to the blue filters 213 of the filter layer. The blue light emitted by the blue sub-pixels 233 may be diffused by the blue filters 213.

In some embodiments, the substrate 24 may be made of transparent plastic, glass, metal foil, or the like. The substrate 24 may be configured to support the entire display screen 20. The display screen 20 may be a hard screen or a flexible screen. If the display screen 20 is a hard screen, the substrate 24 may be a glass substrate. If the display screen 20 is a flexible screen, the substrate 24 may be a polyimide (PI, flexible plastic) substrate.

The embodiments of the present disclosure provide a display screen and a terminal. The display screen comprises a substrate, a light-emitting layer, and a filter layer disposed in sequence. The filter layer comprises a plurality of color filters with diffusion function. The display screen is provided with the color filters, so that light emitted by the light-emitting layer is diffused at various angles through diffusion particles, thereby effectively increasing viewing angles of the display screen of the terminal.

To promote understanding of one or more exemplary embodiments, reference has been made to exemplary embodiments illustrated in the accompanying drawings, and specific language has been used to describe these embodiments. However, this specific language is not intended to limit the scope of the inventive concept, and the exemplary embodiments should be construed to encompass all exemplary embodiments that would normally occur to those skilled in the art.

Words “mechanism”, “element”, “means”, and “configuration” generally refer to, but are not limited to, mechanical or physical embodiments, but can comprise software routines in conjunction with processors and the like.

Specific embodiments illustrated and described herein are exemplary examples of the present invention, and are not intended to limit the scope of the present invention in any way. For sake of brevity, conventional electronics, control systems, software development, and other functional aspects of systems (and components of individual operating components of the systems) may not be described in detail. Furthermore, connecting lines or connectors shown in the accompanying drawings are intended to represent exemplary functional relationships and/or physical or logical couplings between various elements. It should be noted that many alternative or additional functional relationships, physical connections, or logical connections may be present in a practical device. Moreover, no parts or components are indispensable for implementing the present invention unless elements are specifically described as “essential” or “critical”. Technically, words such as “comprise” and “have” used herein have open meanings.

Terms “a/an” and “the”, and similar referents that are used in a description of the inventive concept (especially in the following claims) are to be construed to cover both singular and plural. Furthermore, recitation of ranges of values herein are merely intended to serve as a shorthand method of referring individually to each separate value falling within the range, unless otherwise indicated herein, and each separate value is incorporated into the present specification as if it were individually recited herein. Furthermore, steps of all methods described herein can be performed in any suitable order unless otherwise indicated herein or otherwise clearly contradicted by context. The inventive concept is not limited to a described order of the steps. Use of any and all examples, or exemplary language (e.g., “such as”) provided herein is only intended to better illuminate the inventive concept, and is not intended to limit the scope of the inventive concept unless otherwise claimed. Numerous modifications and adaptations will be readily apparent to those skilled in the art without departing from the scope.

It should be understood that the exemplary embodiments described herein should be regarded as descriptive only, and not for limitation. Descriptions of features or aspects in each of the exemplary embodiments should generally be considered as available for other similar features or aspects in other exemplary embodiments. Although the present invention has been described with the exemplary embodiments, various changes and modifications may be suggested to those skilled in the art. The present invention intends to cover such changes and modifications within the scope of the appended claims.

1. A display screen, comprising:
a substrate;
a light-emitting layer disposed on the substrate; and
a filter layer disposed on the light-emitting layer and comprising a plurality of color filters with diffusion function.

2. The display screen according to claim 1, wherein the color filters are configured to diffuse a light emitted by the light-emitting layer, and comprise a red filter, a green filter, and a blue filter.

3. The display screen according to claim 2, wherein the color filters comprise a plurality of diffusion particles, and when the light passes through the filter layer, the light is diffused out of the display screen at various angles by the diffusion particles.

4. The display screen according to claim 2, wherein the red filter, the green filter, and the blue filter are arranged at intervals, the filter layer further comprises a black matrix, and the black matrix is disposed at the intervals between the red filter, the green filter, and the blue filter.

5. The display screen according to claim 4, wherein the red filter, the green filter, and the blue filter are polygons, and the black matrix is a polygon.

6. The display screen according to claim 1, wherein the color filters comprise a plurality of red filters, green filters, and blue filters, the filter layer further comprises a black matrix, the black matrix comprises a plurality of sub-black matrices, and the red filters, the green filters, the blue filters, and the sub-black matrices are alternately arranged over the entire filter layer.

7. The display screen according to claim 2, wherein the light-emitting layer comprises a red sub-pixel, a green sub-pixel, and a blue sub-pixel that emit light of corresponding colors in a power-on state.

8. The display screen according to claim 7, wherein the red filter, the green filter, and the blue filter are disposed corresponding to the red sub-pixel, the green sub-pixel, and the blue sub-pixel according to same color.

9. The display screen according to claim 1, further comprising a glass layer disposed between the filter layer and the light-emitting layer.

10. The display screen according to claim 9, wherein the glass layer comprises one or more pieces of transparent glass.

11. A terminal, comprising:
a housing;
a circuit board disposed in the housing; and
a display screen electrically connected to the circuit board, disposed in the housing, and comprising a substrate, a light-emitting layer, and a filter layer disposed in sequence, wherein the display screen and the housing form a closed space, and the filter layer comprises a plurality of color filters with diffusion function;
wherein the light-emitting layer and the circuit board are disposed on opposite sides of the substrate.

12. The terminal according to claim 11, wherein the color filters are configured to diffuse a light emitted by the light-emitting layer, and comprise a red filter, a green filter, and a blue filter.

13. The terminal according to claim 11, wherein the color filters comprise a plurality of diffusion particles, and when light passes through the filter layer, the light is diffused out of the display screen at various angles by the diffusion particles.

14. The terminal according to claim 12, wherein the red filter, the green filter, and the blue filter are arranged at intervals, the filter layer further comprises a black matrix, and the black matrix is disposed at the intervals between the red filter, the green filter, and the blue filter.

15. The terminal according to claim 14, wherein the red filter, the green filter, and the blue filter are polygons, and the black matrix is a polygon.

16. The terminal according to claim 11, wherein the color filters comprise a plurality of red filters, green filters, and blue filters, the filter layer further comprises a black matrix, the black matrix comprises a plurality of sub-black matrices, and the red filters, the green filters, the blue filters, and the sub-black matrices are alternately arranged over the entire filter layer.

17. The terminal according to claim 12, wherein the light-emitting layer comprises a red sub-pixel, a green sub-pixel, and a blue sub-pixel that emit light of corresponding colors in a power-on state.

18. The terminal according to claim 17, wherein the red filter, the green filter, and the blue filter are disposed corresponding to the red sub-pixel, the green sub-pixel, and the blue sub-pixel according to same color.

19. The terminal according to claim 11, wherein the display screen further comprises a glass layer disposed between the filter layer and the light-emitting layer.

20. The terminal according to claim 19, wherein the glass layer comprises one or more pieces of transparent glass.
